(19) United States
(12) Patent Application Publication
(10) Pub. No.: US 2020/0386807 A1
(43) Pub. Date: Dec. 10, 2020

(54) AUGMENTED-REALITY-BASED TESTING ANALYSIS AND MODIFICATION

(71) Applicant: HITACHI, LTD., Tokyo (JP)

(72) Inventors: Jia LI, Tokyo (JP); Yuan XIAO, Farmington Hills, MI (US)

(21) Appl. No.: 16/432,967

(22) Filed: Jun. 6, 2019

(51) Int. Cl. G01R 31/28; G02B 27/01; G06T 19/00; G01H 1/00

(52) U.S. Cl. CPC G01R 31/2834; G01H 1/00; G06T 19/006; G02B 27/017

(57) ABSTRACT

In some examples, a computing device may receive, from an electronic device, at least one image of a test setup. The computing device may perform recognition on the image to determine one or more components of the test setup, and may execute a simulation of the test setup based at least partially on the one or more components. Based on the simulation indicating that the test setup does not meet a specification, the computing device may compare a plurality of valid setups with the test setup. The computing device may select one of the valid setups based on the comparing, and may determine one or more instructions for modifying the test setup based on the selected valid setup. Further, the computing device may send the one or more instructions to the electronic device to enable presentation of the instructions on a display of the electronic device.

### BACKGROUND

Some types of vehicles, such as hybrid or electric vehicles (HEV/EVs), may be propelled by an inverter-motor system that converts high-voltage DC (Direct Current) from a high voltage battery pack to 3-phase AC (Alternating Current) variable frequency/amplitude voltages for driving one or more 3-phase electric motors. This DC-AC conversion may include high-speed interruption of voltage and current and is usually realized by using semiconductor switches such as IGBTs (Insulated-gate Bipolar Transistors), which may be located inside the power modules of power electronic devices. This high-speed switching includes steep changes in voltage and current, which can cause electromagnetic interference (EMI) to onboard electronic devices, such as radios or the like.

To reduce EMI effects, inverters may undergo substantial electromagnetic compatibility (EMC) testing to ensure EMC compliance before providing these devices to vehicle manufacturers or other original equipment manufacturers (OEMs), or the like. EMC tests are regulated by international standards such as CISPR (Comite International Special des Perturbations Radioelectriques) and IEC (International Electrotechnical Commission), as well as some OEMs' own EMC requirements. For example, a radiated emission (RE) test for an inverter-motor drive system is set forth in the international standard CISPR25 with the purpose of protecting any on-board receivers from RE EMI disturbances.

During testing, the measured RE noise level may be sensitive to the test setup, such as the wiring harness or cable layout. To improve consistency of RE testing, test plans may be prepared to formalize details before starting an RE test. However, some parts, especially cable or harness layout, may be difficult to specify precisely, which can possibly cause variations in each test. Consequently, computer simulations in which the models may be built based on the test setup information defined in the test plans may not reflect the actual or in-situ test setup. This may cause discrepancies between the simulated RE noise levels and the measured RE noise levels. Therefore, trial and error methods are used conventionally for troubleshooting the EMC issues in an RE test. As one example, when EMC noncompliance occurs, EMC engineers may first exclude the influences caused by these variations by changing the layouts and re-testing before moving on to a next phase, such as troubleshooting with circuit modifications. This work can be repetitive, which can cause added costs and time delays.

### SUMMARY

Some implementations include arrangements and techniques for augmented-reality-based testing modification. In some examples, a computing device may receive, from an electronic device, at least one image of a test setup. The computing device may perform recognition on the image to determine one or more components of the test setup, and may execute a simulation of the test setup based at least partially on the one or more components. Based on the simulation indicating that the test setup does not meet a specification, the computing device may compare a plurality of valid setups with the test setup. The computing device may select one of the valid setups based on the comparing, and may determine one or more instructions for modifying the test setup based on the selected valid setup. Further, the computing device may send the one or more instructions to the electronic device to enable presentation of the instructions on a display of the electronic device.

### BRIEF DESCRIPTION OF THE DRAWINGS

The detailed description is set forth with reference to the accompanying figures. In the figures, the left-most digit(s) of a reference number identifies the figure in which the reference number first appears. The use of the same reference numbers in different figures indicates similar or identical items or features.

FIG. 1 illustrates an example configuration of a system able to be used to perform testing for electromagnetic interference according to some implementations.

FIG. 2 illustrates an example process for adjusting a test setup for performing a test according to some implementations.

FIG. 3 illustrates an example of the recognition module according to some implementations.

FIG. 4 illustrates an example of the information module according to some implementations.

FIG. 5 illustrates an example of the simulation module according to some implementations.

FIG. 6 illustrates an example of the instruction module according to some implementations.

FIGS. 7A and 7B illustrate example views of the display of the AR device according to some implementations.

FIG. 8 illustrates an example process for vibrational testing according to some implementations.

FIG. 9 illustrates an example of the simulation module according to some implementations.

FIG. 10 illustrates an example process for vibrational and acoustic (vibro-acoustic) testing according to some implementations.

FIG. 11 illustrates an example of the simulation module according to some implementations.

FIG. 12 is a flow diagram illustrating an example process executed by the AR device according to some implementations.

FIG. 13 illustrates select components of the service computing device(s) according to some implementations.

FIG. 14 illustrates select example components of the AR device according to some implementations

### DETAILED DESCRIPTION

Some implementations herein are directed to techniques and arrangements for augmented-reality-based in-situ EMC testing and analysis that employs augmented reality (AR) with machine learning to improve EMC testing technology. For instance, an AR device may enable a user to view the in-situ test layout and receive a real-time analysis of the test layout and information for improving the configuration of the test layout. The AR device may communicate with a computing device, such as a cloud-based server or other network computing device, by uploading visualized layout information and receiving an analysis result following an analysis performed by the computing device.

In some examples, the computing device may determine one or more adjustments to the test layout configuration based on the analysis. For instance, the computing device may use one or more machine learning models to recognize and analyze the visualized layout information sent by the AR device for determining an adjustment to the test layout configuration. In some cases, the analysis may include performing recognition of various components and recognition of the overall layout of the components with respect to each other. The analysis may further include execution of a high-fidelity simulation that is performed using the recognized information. In addition, the simulated results may be compared with one or more specifications for determining EMC compliance with the one or more specifications.

In the case that the likelihood of EMC noncompliance with the one or more specifications exceeds a threshold level, an instruction module may be initiated to evaluate various changes in the configuration of the test layout to determine an optimal change most likely to improve the configuration of the test layout for complying with the one or more specifications. Based on the determined optimal change, the computing device may send an instruction to the AR device for instructing the change to the test layout configuration.

The AR device may receive the instruction from the computing device and may present information corresponding to the instruction on a display of the AR device. For example, the AR device may include one or more processors, an output device, such as head-mounted display, a communication interface, one or more cameras for providing a real-time view of the test layout, as well as various other input devices, such as sensors (e.g., accelerometer, GPS (global positioning system) receiver, solid-state compass, and so forth).

The AR device may serve as a medium for a user to interact with the test setup, while the algorithms for analyzing and providing information to the user about the test setup may be executed on the computing device(s), e.g., in the cloud, on one or more local devices, combinations thereof, or the like. For instance, a user may use the head-mounted display of the AR device to receive an instruction based on an analysis result, which may include step-by-step guidance, or the like, presented overlaid on an image of the test layout presented on the display. Further, the sensors in the AR device may be used to track the movement of the user, and the camera(s) may be used to capture the in-situ reality of the test setup for enabling the computing device(s) to process and identify details of the test layout.

In addition, the one or more processors onboard the AR device may include a certain level of computation capability to enable the AR device to display AR information on the display, such as for overlaying information on a view of the test setup, while computationally intensive data processing may be performed on the computing device(s), such as at a remotely located backend cloud server. The one or more processors on the AR device may execute an AR device program that may cause the AR device to perform functions for receiving data through the camera and other sensors, and for sending the data from the AR device to the computing device(s) for analysis. In response, the AR device may receive one or more instructions or other information from the computing device(s), such as for adjusting a test setup configuration or the like. The one or more instructions may be overlaid on the display of the AR device, such as for providing step-by-step instructions to the user for making one or more adjustments to the test setup. The adjustment(s) to the test setup may result in an optimal configuration of the test setup for performing RE EMC testing for the particular equipment included in the test setup.

Implementations herein solve the problems of the conventional approaches for troubleshooting EMC issues in RE test setups, which are still based on trial and error methods. For instance, RE noise is sensitive to the test setup configuration, such as cable or harness layout, equipment location with respect to other equipment, and so forth. Accordingly, when EMC noncompliance occurs, EMC engineers may first try to exclude the influences caused by these variations by changing the layouts and re-testing before moving on to other phases, such as performing circuit modifications. This process may be repetitive and time consuming, which causes extra costs and delays. However, in the implementations herein, an AR-based in-situ EMC analysis technology is disclosed that saves time and reduces costs by avoiding the performance of repetitive tests due to test layout changes. As discussed additionally below, the AR based in-situ analysis technology herein may also be used for other fields such as vibrational tests and vibro-acoustic tests where real-time and in-situ analysis may be employed.

For discussion purposes, some example implementations are described in the environment of an RE EMC testing layout. However, implementations herein are not limited to the particular examples provided, and may be extended to other types of equipment, other environments of use, other system architectures, other applications, and so forth, as will be apparent to those of skill in the art in light of the disclosure herein.

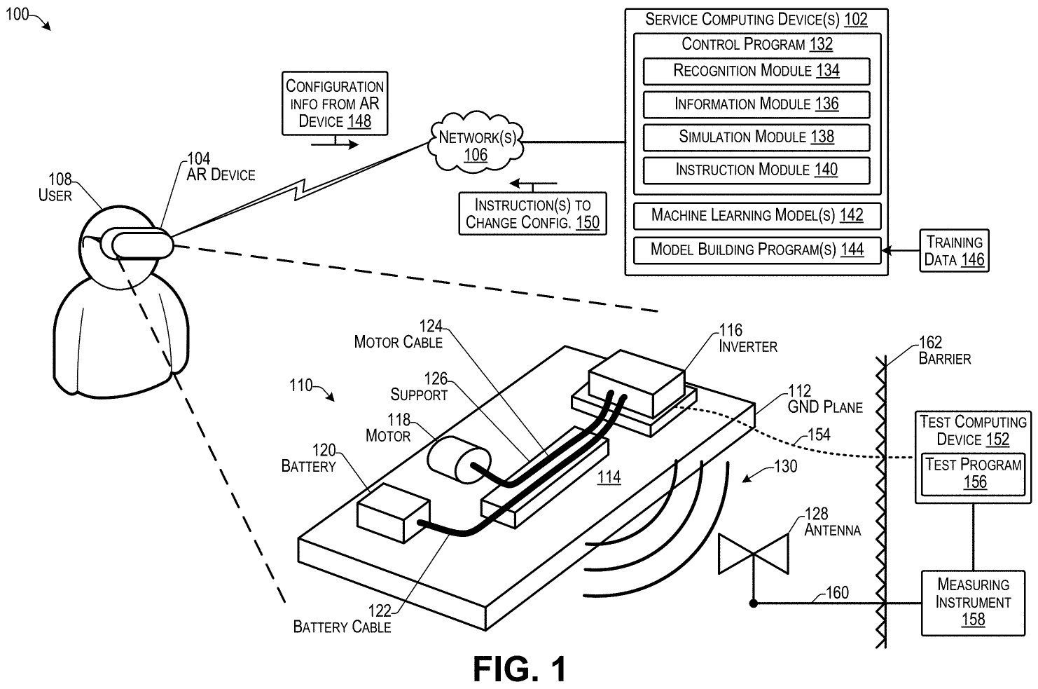

FIG. 1 illustrates an example configuration of a system 100 able to be used to perform testing for electromagnetic interference according to some implementations. The system 100 includes one or more service computing devices 102 that are able to communicate directly or indirectly with an augmented reality (AR) device 104, such as by direct connection, over one or more networks 106, combinations thereof, or the like. For example, the AR device 104 may send information to the service computing device(s) 102 and/or may receive information from the service computing device(s) 102 over the one or more networks 106.

The AR device 104 may be used by a user 108 for interacting with a test setup 110. For instance, as mentioned above, electronic components may be required to go through various validation tests such as EMC tests to ensure compliance with various regulations and/or customer requirements. However, the outcomes of these tests can often depend on the test setup and procedures. Test plans and specifications may be prepared in advance to formalize details before performing a test. However, some parts of the testing, such as component layouts may be difficult to specify precisely and may cause possible variations during testing. Accordingly, when noncompliance occurs during testing the user may first try to exclude any influence caused by variations in the test setup configuration, such as by changing one or more parts of the test setup configuration and re-testing before moving onto a next phase, such as troubleshooting or modifying circuits being tested, or the like.

In the illustrated example, the test setup 110 includes a ground (GND) plane/common return path 112 (referred to hereinafter as “ground plane 112”), which may include one or more surfaces 114 upon which the test setup may be configured. In this example, an inverter 116, a motor 118, and a battery 120 are disposed on the surface 114. A battery cable 122 connects the battery 120 to the inverter 116 for supplying high voltage DC to the inverter 116. A motor cable 124 connects the motor 118 to the inverter 116 for supplying AC power to the motor 118. The battery cable 122 and/or the motor cable 124 may be disposed at least partially on a support 126. In addition, at least one antenna 128 may be located proximate to the ground plane 112, such as for receiving radiated emissions 130 during testing. Furthermore, implementations herein are not limited to any particular test setup configuration or tested components. Consequently, other test setups, test setup components, test setup configurations, and so forth, may be employed according to the implementations herein.

The one or more networks 106 may include any type of network, including a LAN, such as an intranet; a WAN, such as the Internet; a wireless network, such as a cellular network; a local wireless network, such as Wi-Fi; short-range wireless communications, such as BLUETOOTH®; a wired network including fiber optics, Ethernet, Fibre Channel, or any other such network, a direct wired connection, or any combination thereof. Accordingly, the one or more networks 106 may include both wired and/or wireless communication technologies. Components used for such communications can depend at least in part upon the type of network, the environment selected, or both. Protocols for communicating over such networks are well known and will not be discussed herein in detail.

The service computing device(s) 102 may include one or more servers or any of various other types of computing devices that may be embodied in any number of ways. For instance, in the case of a server, executable programs, other functional components, and data may be implemented on a single server, a cluster of servers, a server farm or data center, a cloud-hosted computing service, and so forth, although other computer architectures may additionally or alternatively be used. For instance, in other cases, the service computing device(s) 102 may be embodied by one or more personal computers, workstations, laptops, servers, combinations thereof, or the like.

The service computing device(s) 102 may execute a control program 132 that may include a recognition module 134, an information module 136, a simulation module 138, and an instruction module 140. In addition, the service computing device(s) 102 may store or may access one or more machine learning models 142 and one or more model building programs 144. For instance, the model building program(s) 144 may access training data 146 that may be used for building and training the machine learning model(s) 142.

The recognition module 134 may perform an algorithm that includes recognition of various components and recognition of the overall layout of the components with respect to each other. The information module 136 may receive recognition results from the recognition module 134 and may access component data, historical test setup layout data, and the like, and may assemble a circuit diagram or the like to provide to the simulation module 138. The simulation module 138 may execute a high-fidelity simulation using the recognized information provided by the recognition module 134 and the information module 136 to determine a simulated result of the EMC test setup using the recognized components and recognized test setup configuration. The instruction module 140 may compare the simulated results with one or more specifications for determining EMC compliance with the one or more specifications, and may determine one or more instructions to provide to the AR device based on the comparison and one or more specifications.

As discussed additionally below, in some examples, some or all of the modules 134-140 may employ one or more of the machine learning models 142. Examples of the machine learning model(s) 142 may include classification models such as random forest, support vector machines, or deep learning networks. Additional examples of the machine learning models 142 may include predictive models, decision trees, regression models, such as linear regression models, stochastic models, such as Markov models and hidden Markov models, artificial neural networks, such as recurrent neural networks, and so forth, depending on the application for the particular machine learning model. Accordingly, implementations herein are not limited to a particular type of machine learning model. Additionally, the system 100 may employ one or more application programming interfaces (APIs) (not shown in FIG. 1) to enable the various programs and/or modules herein to interact with each other for communicating and processing information related to the test setup 110.

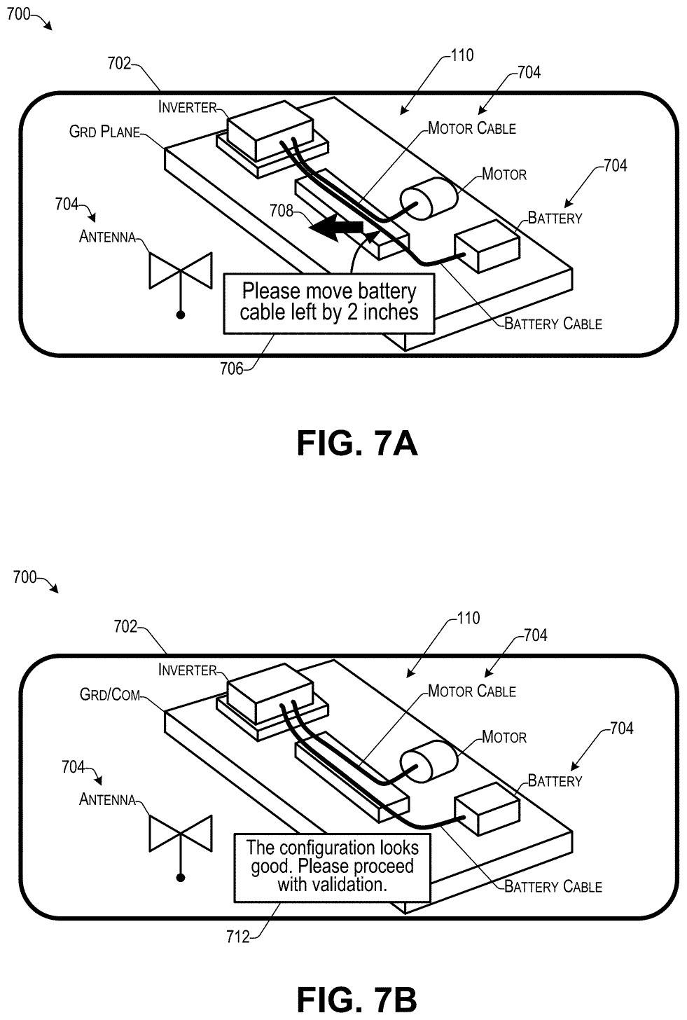

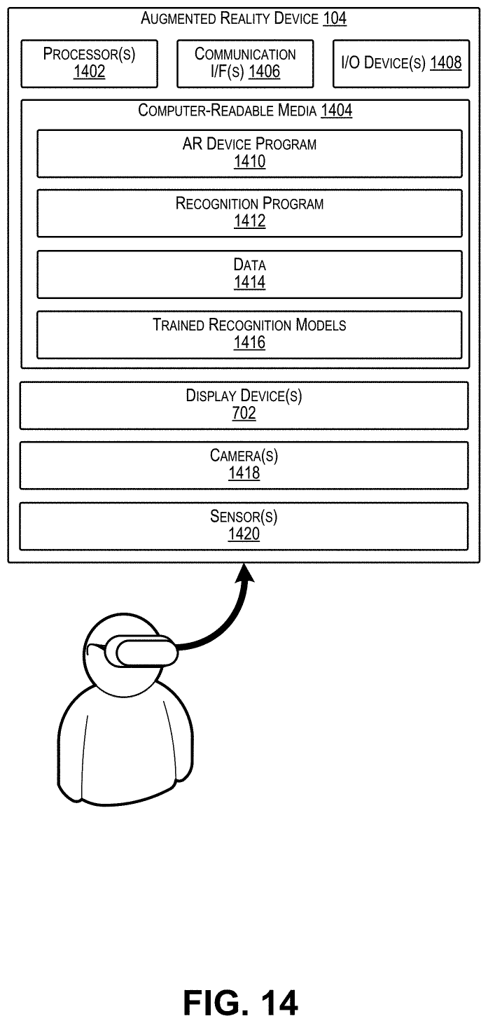

As one example, the user 108 may use the AR device 104 to view the test setup 110. One or more cameras on the AR device 104 may capture images, video, etc., of the test setup 110. In some cases, the view of the one or more cameras may be wholly or partially presented on a display of the AR device 104, such that the view of the user 108 when wearing the AR device 104 is actually a video image. In other cases, the user may be able to view through the at least a portion of the display on the AR device for viewing the actual test setup 110 with additional information presented on the display by the AR device 104, such as component names, test information, and the like. Additional details of the view of the user 108 and the AR device are discussed below, e.g., with respect to FIGS. 7A, 7B and 14.

The AR device 104 may send configuration information 148 to the service computing device(s) 102. As mentioned above, the service computing device(s) 102 may use the recognition module 134, the information module 136, the simulation module 138, and the instruction module 142 perform an analysis of the configuration information 148 received from the AR device 104. In response to the configuration information 148 received from the AR device 104, the instruction module 140 may send one or more instructions 150 to the AR device 104 to change the configuration of the test setup 110.

The AR device 104 may receive the instruction(s) 150 or other information from the service computing device(s) 102, such as for adjusting the configuration of the test setup 110, or the like. As one example, the instruction(s) 150 may be overlaid on the display of the AR device 104, such as for providing step-by-step instructions to the user 108 for making one or more adjustments to the test setup 110. The adjustment(s) to the test setup 110 may result in an optimal configuration of the test setup 110 for performing RE EMC testing for the particular equipment included in the test setup 110.

Additionally, in some examples, the test setup may include a test computing device 152 or other type of controller that may be connected to one or more of the inverter 116, the battery 120, the motor 118, or the like, by one or more control lines 154 that may execute a test program 156 for controlling the test setup 110 such as for executing an EMC test and for monitoring the test results. For instance, the test computing device 152 may receive input from a measuring instrument 156 that is connected to the antenna 128 by a line 160 for measuring the radiated emissions 130 detected by the antenna 128. The test computing device 152 and the measuring instrument 158 may be on the opposite side of a barrier 162, such as a wall or the like, which may include an RF-absorbing material to prevent interference with the test results. In some cases, the test computing device 152 may be in communication with the network(s) 106, and may be able to communicate with the service computing device(s) 102 and/or the AR device 104, such as for providing test conditions, measurement instrument information, simulation parameter settings, and so forth, as discussed additionally below. Further, while one example, of a test setup 110 is illustrated in FIG. 1, numerous other variations will be apparent to those of skill in the art having the benefit of the disclosure herein.

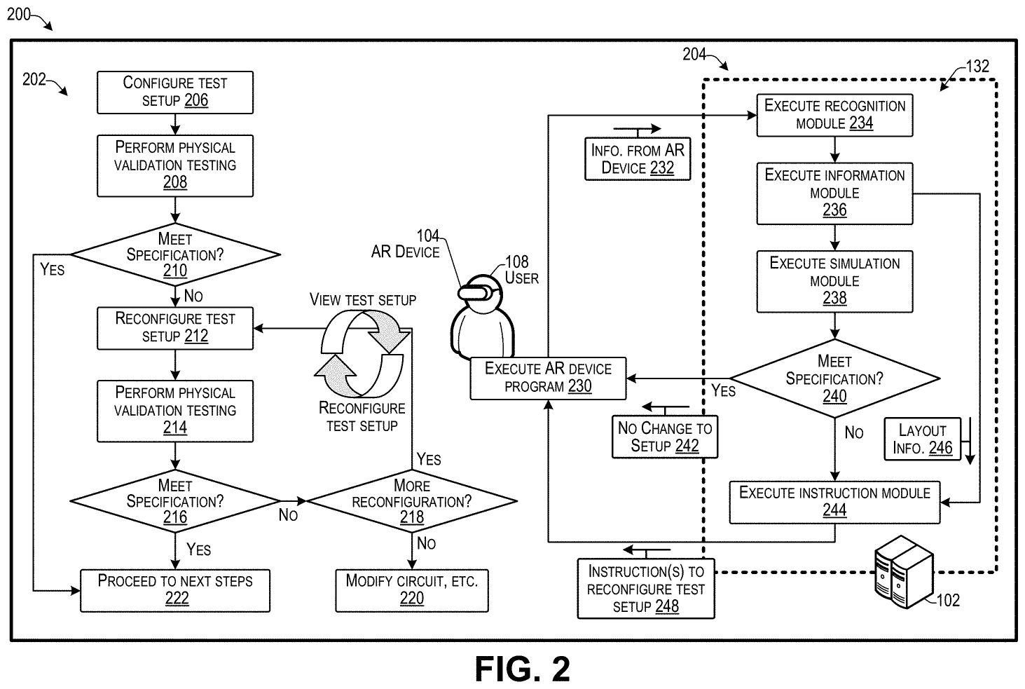

FIGS. 2-6 and 8-12 include flow diagrams illustrating example processes according to some implementations. The processes are illustrated as collections of blocks in logical flow diagrams, which represent a sequence of operations, some or all of which may be implemented in hardware, software or a combination thereof. In the context of software, the blocks may represent computer-executable instructions stored on one or more computer-readable media that, when executed by one or more processors, program the processors to perform the recited operations. Generally, computer-executable instructions include routines, programs, objects, components, data structures and the like that perform particular functions or implement particular data types. The order in which the blocks are described should not be construed as a limitation. Any number of the described blocks can be combined in any order and/or in parallel to implement the process, or alternative processes, and not all of the blocks need be executed. For discussion purposes, the processes are described with reference to the environments, frameworks, and systems described in the examples herein, although the processes may be implemented in a wide variety of other environments, frameworks, and systems.

FIG. 2 illustrates an example process 200 for adjusting a test setup for performing a test according to some implementations. In this example, a test process 202 may be performed at least partially by the user 108 and partially by the test equipment in the test setup, such as in the test setup 110 discussed above with respect to FIG. 1. Further, a control process 204 may be executed by the service computing device(s) 102, such as by executing the control program 132 discussed above with respect to FIG. 1, as indicated by the blocks within the dashed rectangle.

In the test process 202, at 206, the user 108 may configure the test setup. For example, the user 108 may configure the test setup according to one or more specifications provided by the designer of the equipment being tested, provided by a governmental authority, and/or provided by an OEM.

At 208, the physical validation testing may be performed. As one example, as discussed above with respect to FIG. 1, the test program 156 on the test computer 152 may be executed to perform a physical validation test and measurement of emitted radiation.

At 210, at least one of the test program 156 or the user 108 may receive the results of the testing, and may determine whether the tested equipment meets the required specification for the equipment. If the results meet the specification, the process may go to 222 to proceed with the next steps for validation of the equipment being tested. If the results do not meet with the specification, in conventional techniques, the user may attempt one or more trial and error adjustments to the test setup. However, in implementations herein, instead of trial and error, the user may employ the AR device 104 to determine how to reconfigure the test setup at 212 to an optimal recommended setup. This enables the user 108 to exclude possible influences caused by variations in changing the layouts and re-testing before moving onto next phase such as troubleshooting with circuit modifications.

At 212, based on use of the AR device 104 as discussed additionally below, the user may receive one or more instructions to reconfigure the test setup, and may reconfigure the test setup according to the instruction(s).

At 214, the physical validation testing may be performed. As one example, as discussed above with respect to FIG. 1, the test program 156 on the test computer 152 may be executed to perform the physical validation test and measurement of emitted radiation. Blocks 212 and 214 may typically be performed only once or several times in some cases.

At 216, the user or the test program may determine if the specification is met. If so, the process goes to 222 to perform the next steps. If not, the process goes to 218.

At 218, if the specification is still not met, the process may determine whether more reconfiguration should be performed. For example, as discussed below, if no change is recommended to the test setup, then, at this point, the test setup may be presumed to be in an optimal configuration for a valid test setup if no further configuration changes are recommended, and the process may go to 220. On the other hand, if the service computing device provides additional instructions for reconfiguration, the process may return to 212. For example, the user 108 may use the AR device 104 to view the current test setup, providing the current setup information to the service computing device(s) 102, receive additional instructions from the service computing device(s) 102, reconfigure the test setup based on the additional instructions, and re-execute the physical validation testing at 214.

At 220, if the test setup does not meet the specification and no more reconfiguration instructions are received, the user 108 may perform other actions, such as troubleshooting or modifying one or more circuits of the equipment being tested, or the like.

At 222, when the specification has been met, the next steps in validation may be performed, as is known in the art.

Referring now to the processes performed by the AR device 104 and the service computing device(s) 102, at 230, the user 108 may employ the AR device 104 if the test specification is not met at 210 or 216, which may cause one or more processors of the AR device 104 to execute an AR device program. For example, the AR device program may capture one or more images or other information about the test setup, and may send this information 232 from the AR device to the service computing device(s) 102. The AR device 104 enables the user 108 to look at the in-situ test layout and receive analyzed results and corresponding instructions in real time or near-real time. The AR device 104 communicates with the service computing device(s) 102 by sending information 232 from the AR device to the service computing device(s) 102, such as over one or more networks. For instance, the information 232 may include visualized test setup configuration information (e.g., one or more images of the test setup) and/or other information about the testing being performed and/or the test setup.

In some cases, the user 108 may wear the AR device 104 as a head mounted display that may present step-by-step instructions for adjusting the test setup configuration and/or other analysis results. One or more sensors may be included onboard the AR device 104, such as to track the movement of user wearing the AR device relative to the test setup, or the like. One or more cameras included with the AR device may be used to capture images of the in-situ reality of the test setup, which may be sent to the service computing device(s) to enable recognition and analysis of the test setup configuration and any possible adjustments to the test setup layout or the like. One or more processors may be included as part of the AR device that may have sufficient processing capability to present images on the display device(s) of the AR device, as well as for communicating with the service computing device(s) 102, such as for sending images and other information, and for receiving analysis results and/or instructions from the service computing device(s) 102. For instance, an AR device program may be executed by the one or more processors of the AR device 104 for controlling functions of the AR device and for communicating with the service computing device(s) 102.

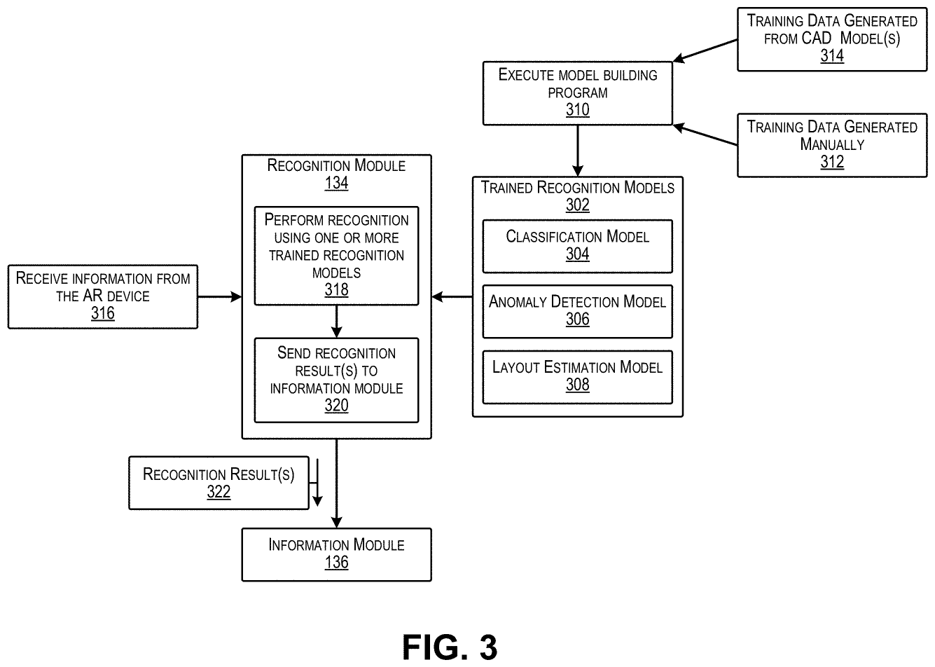

At 234, the control program 132 may receive the information 232 from the AR device, and may execute the recognition module to perform recognition of one or more received images included in the information 232 from the AR device. For example, the recognition module may apply one or more machine learning models to determine the components included in the test setup, detect any anomalies, and perform a layout estimation. The recognition results may be provided to the information module. Additional details of the recognition module are discussed below, e.g., with respect to FIG. 3.

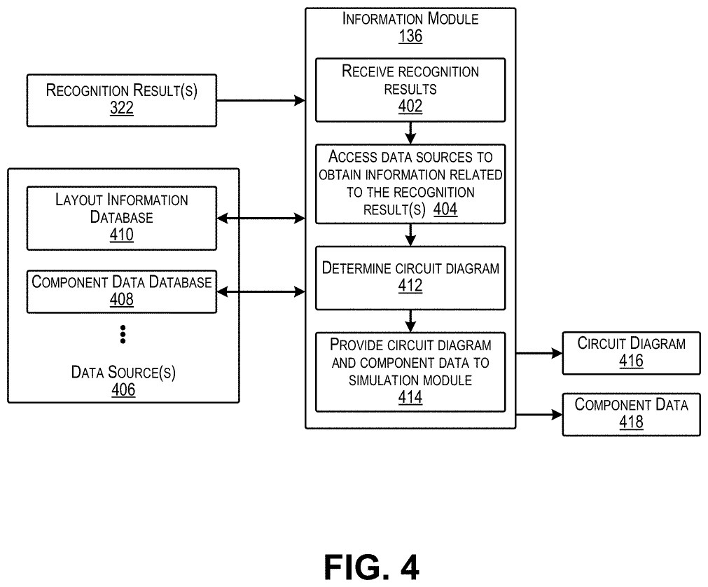

At 236, the control program 132 may execute the information module to obtain information about the recognized components and the test setup. For example, the information module may obtain component data and layout data from one or more databases or other sources, and may automatically generate a circuit diagram corresponding to the test setup. Additional details of the information module are discussed below, e.g., with respect to FIG. 4.

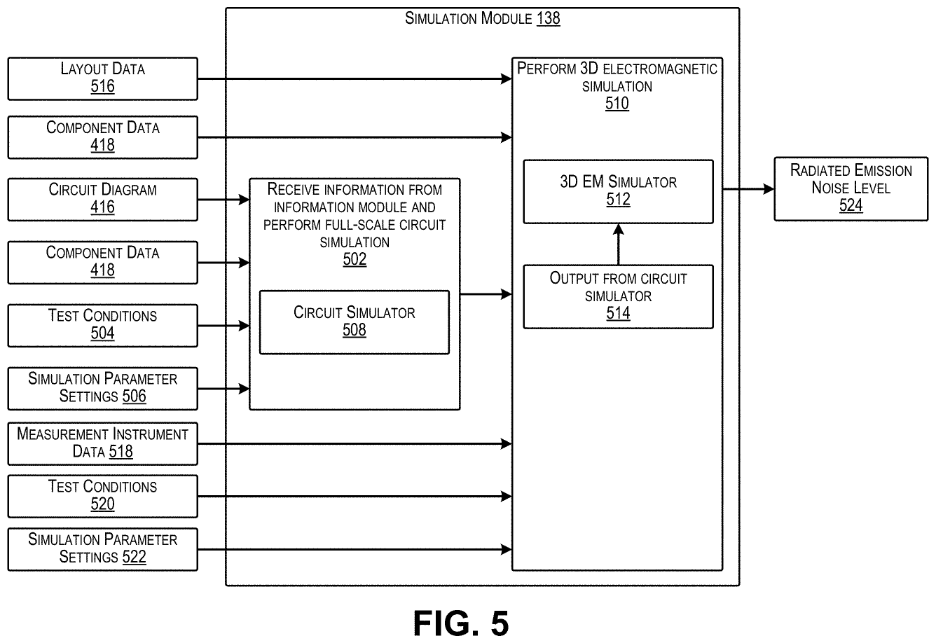

At 238, the control program 132 may execute the simulation module using the results of the information module and the recognition module. For example, the simulation module may include a circuit simulator and an electromagnetic interference (EMI) simulator. The simulation module may receive the layout data and circuit diagram information from the information module. In addition, the simulation module may receive test conditions, simulation parameter settings, and measurement instrument data from the information module or from other sources. The simulation module may execute the circuit simulator and the EMI simulator, and may determine a radiated emission noise level as a result. Additional details of the information module are discussed below, e.g., with respect to FIG. 5.

At 240, the control program 132 may compare the simulated result with the one or more specifications. If the result of the simulation module meets the specification, then the control program may send a result to the AR device 104, such as an indication of no change to the setup 242. Alternatively, if the simulated result does not meet the specification the process may move to block 244 to execute the construction module.

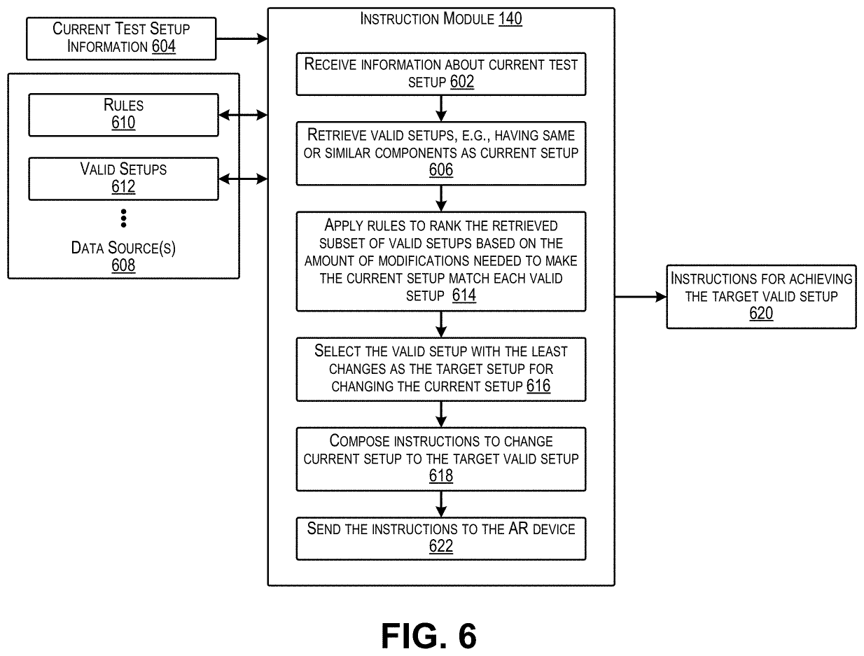

At 244, in the case that the simulation result does not meet the specification at 240, the control program 132 may execute the instruction module. The instruction module 246 may repeat the execution of the simulation module 238 with various changes in the layout configuration of the test setup to determine an optimal change to the configuration of the test setup. For example, the instruction module may receive the layout information 246 of the current setup, as well as information about other valid setups and one or more rules to apply for determining an optimal test setup. The instruction module may determine one or more instructions for achieving the optimal set up and may send instructions 248 for reconfiguring the test setup to the AR device 104 to instruct the user 108 to make one or more layout changes. Additional details of the instruction module are discussed below, e.g., with respect to FIG. 6.

Returning to block 230, the AR device program may receive the instructions 248 to reconfigure the test setup, and may display the instructions on the display device(s) of the AR device 104. As one example, the instructions 248 may be displayed in a step-by-step manner to the user to instruct the user specifically how to reconfigure the test setup.

FIG. 3 illustrates example details of the recognition module 134 according to some implementations. The recognition module 134 may include executable code and may be a portion of the control program 132 (not shown in FIG. 3) executable on the service computing device(s) 102. Alternatively, in other examples, the recognition module 134 may be a separate program from the control program 132. Additionally, in some examples, the recognition module 134 or a similar program may be executable on the AR device 104, such as for enabling the AR device program to present, on the display device(s) of the AR device 104, labels or other information about the components used in the test setup.

In the illustrated example, the recognition module 134 may employ one or more trained recognition models 302, such as a classification model 304, an anomaly detection model 306, and a layout estimation model 308. For instance, as indicated at 310, the control program 132 may execute the model building program 144 (discussed above with respect to FIG. 1) to generate and train the trained recognition models 302. As one example, each of the three models 304, 306, 308 may be trained separately using training data 312 generated manually and/or training data 314 generated from CAD models or simulations. In particular, the classification model 304 may be trained to categorize each component and identify the 3D dimensions of each component included in the test setup. Further, the layout estimation model 308 may be trained to use the results from classification model 304 as a reference and identify the relative positions of each of the components included in the test setup in 3D space.

In addition, the anomaly detection model 306 may be trained to use the results of the classification model 304 and the layout estimation model 308 as inputs for determining if there is any anomaly with the test setup. Since it is desirable for the recognition models 302 to have high accuracy to be suitable for detecting anomalies with the test setups, large amounts of labelled training data may be employed to increase the fidelity of these models. Accordingly, as generating training data 312 manually may be very time consuming and may still lack fidelity due to human fallacy, implementations herein may additionally, or alternatively use a 3D CAD model to automatically generate training data of each angle of each component of the test setup, as well as for the overall layout of the test setup.

After the recognition models 302 have been trained and tested or otherwise verified, the recognition models 302 may be used to process the test setup layout and output recognition results to information module in real-time. For instance, as indicated at 316, the recognition module 134 may receive information from the AR device, such as one or more images of the test setup, information about the test being conducted, information about the specification to be met, and so forth.

At 318, the recognition module may be executed to perform recognition on the information received from the AR device using the trained recognition models 302 to identify each component in the test setup and the overall layout dimensions and positions of the components relative to each other. In some cases, the anomaly detection model 306 may further determine and report detected anomalies, such as whether any components are missing from the test setup, whether the layout of the test setup is not according to one or more standards, or the like.

At 320, the recognition module may provide the recognition result 322 to the information module 136. For instance, as discussed above, the information module 136 may be executed to receive the recognition result 322 and obtain information corresponding to the recognition result 322.

FIG. 4 illustrates example details of the information module 136 according to some implementations. At 402, the information module 136 receives the recognition result(s) 322 from the recognition module. At 404, based on the received recognition result(s) 322 the information module 136 retrieves related information from one or more data sources 406, such as one or more databases, web servers, or any of various other data sources, as is known in the art. For example, based on the component recognition results 322, the information module 136 may access a component data database 408 and a layout information database 410 to obtain component data and layout information related to the recognition results 322.

At 412, based on the information received from the data sources 406, the information module 136 may automatically assemble a circuit diagram corresponding to the recognition results 322. For example, the information module may access the layout information database to identify a layout that most closely resembles the current test setup based on the recognized results and recognized components, as determined by the recognition module 134. At 414, the information module 136 may provide the circuit diagram 416, and the component data 418 to the simulation module, which may perform a simulation based on this input as, discussed additionally below with respect to FIG. 5.

FIG. 5 illustrates example details of the simulation module 138 according to some implementations. The simulation module 138 may be executed to perform a high fidelity simulation of the recognized test setup and components. At 502, the simulation module receives information from the information module and performs a full-scale circuit simulation. As inputs, the simulation module 138 may receive the circuit diagram 416 and the component data 418 from the information module as discussed above with respect to FIG. 4. In addition, the inputs may include test conditions 504 and simulation parameters 506. For example, the test conditions 504 and the simulation parameters 506, such as simulation time, time steps, and so forth, either may be provided/updated by the user 108, or may be pre-defined as test conditions 504 and simulation parameters 506 may typically be determined in advance and may remain unchanged through the simulation process. As one example, the test computing device 152 discussed above with respect to FIG. 1 may be used to provide test conditions and/or simulation parameters to the simulation module 138.

The inputs 416, 418, 504 and 506 may be inputted into a circuit simulator 508, which may be a commercially available circuit simulator program executable for determining current amounts in various components and locations within the circuit corresponding to the circuit diagram 416. For example, the full-scale circuit simulation may be used to calculate the loop noise current for the test setup. Circuit simulators are well known in the art and the particulars of executing the circuit simulation are not described in detail herein.

At 510, the simulator module 138 may perform a 3D electromagnetic (EM) simulation using a commercially available 3D EM simulator 512. For example, the 3D EM simulator 512 may simulate in three dimensions the magnetic fields generated by the current passing through the test setup layout during a test procedure. Electromagnetic simulators are well known in the art and the particulars of executing the electromagnetic simulation are not described in detail herein.

The 3D EM simulator 512 receives, as an input, the output 514 from the circuit simulator 508. For example, the output 514 may include a calculated loop noise current, which may indicate current levels at various components/locations of the test setup during the testing. Additional inputs received by the 3D EM simulator 512 may include layout data 516 and the component data 418, which may be obtained from the information module. For example, the layout data 516 may include the locations of the components in the test setup in relation to each other, e.g., dimensions of the components, their distances from each other, and so forth. In some cases, the layout data 516 from information module may be used to update a pre-stored 3D test layout model previously provided by the user.

In addition, the EM simulator 512 may receive, as an input, measurement instrument data 518, which may include antenna factors, cable attenuation data, and the like. For instance, the measurement instrument data 518 may be provided by the user, such as through the test computing device 152 discussed above with respect to FIG. 1, or may be pre-defined, as this information is usually known in advance of the testing. Additional inputs may include test conditions 520 and simulation parameter settings 522, which may typically be determined in advance and may remain unchanged through the simulation process. As one example, the test computing device 152 discussed above with respect to FIG. 1 may be used to provide the test conditions and/or simulation parameters to the 3D EM simulator 512.

The EM simulator 512 may be executed to calculate the RE EMI noise levels expected to be produced by the test setup. For example, the simulation module 138 may execute the 3D EM simulator 512 to simulate how much radiation emission noise is produced by the calculated loop noise current based on the real-time in-situ test setup information. Further, the 3D EM simulation may be performed to simulate RE EMI noise levels at a plurality of specified different frequency bands. The output of the 3D EM simulator 512 may be a radiated emission noise level 524 (e.g., a plurality of predicted noise levels, a distribution of noise levels, etc.) that the control program may compare with the specification for the equipment being tested, as discussed above with respect to FIG. 2, block 240, to determine whether the simulated test layout meets the specification. As mentioned above, if the specification is met, then no change to the test setup is recommended. On the other hand, if the specification is not met, the control program may execute the instruction module to determine one or more changes to the test setup.

FIG. 6 illustrates example details of the instruction module 140 according to some implementations. As mentioned above, in some cases, the instruction module 140 may only be executed if the simulation module determines that the current test setup does not meet the specification.

At 602, the instruction module 140 may receive current test setup information 604, which includes data about the current test setup, such as the layout information, components included in the test setup, type of testing, and so forth.

At 606, the instruction module 140 may access one or more data sources 608 that may include one or more databases or the like that include one or more rules 610 and a plurality of valid test setups 612. For instance, the instruction module may retrieve information about the valid setups 612 that have met the specification(s) in the past. Further, the instructions module may apply one or more rules 610 for filtering the valid setups 612 retrieved from the database. For instance, the rules 610 may be based on the current setup to ensure that a subset of selected valid setups 612 are close enough to the current setup to minimize modification. One example of a rule 610 is to ensure that the retrieved subset of valid setups have the same or similar components as the current setup.

At 614, the instruction module 140 may apply additional rules 610 to rank the valid setups in the subset of valid setups. For instance, the instruction module 140 may compare each valid setup in the subset with the current setup one by one, and may calculate how many modifications might be required to be made to the current setup. Based on the number of modifications, the instruction module 140 may assign a score to each of the selected valid setups to enable ranking of all the valid setups in the subset according to score based on the number of modifications.

At 616, the instruction module 140 may select the valid setup with the score indicating the least changes to the current setup as the target set up before changing the current setup. For instance, based on the ranking, the instruction module may select the valid setup in the subset with the score indicating the minimum number of modifications.

At 618, the instruction module may compose instructions to change the current setup to the target valid setup selected at 616. For example, the instruction module 140 may determine the difference between the target valid setup and the current valid setup, and may compose instructions based on the determined differences for changing the current valid setup configuration to match that of the target valid setup.

At 620, the instruction module may send instructions 622 for achieving the target valid setup to the AR device for implementing the target setup at the current test setup. Upon receipt of the instructions, the AR device may display the instructions to the user on the display device(s) of the AR device to provide step-by-step instructions to the user for implementing the target set up at the current test setup.

FIGS. 7A and 7B illustrate example views 700 and 710, respectively, of the display of the AR device according to some implementations. For example, one or more display device(s) 702 may present the view 700 that includes the current test setup 110 visible either through the display device(s) 702 or presented as a video image. In some examples, the view 700 may include labels 704 of each of the components of the test setup to enable the user to identify components referred to by the instructions.

In addition, the AR device may present the instructions on the display device(s) 702 in a step-by-step manner such as by presenting a pop-up window, banner, overlay, or other text 706, on the display device(s) 702. For example, detailed instructions including, e.g., one or more arrows or other graphic elements 708 may also be presented on the display device(s) 702 to help guide the user in modifying the test setup 110. In addition, in some cases, text to speech conversion may also be used to provide oral instructions to the user in addition to, or as an alternative to, the text instructions 706. While the user is performing the modifications to the test setup 110, the AR device may continually analyze the changes and provide additional real-time instructions until the user has completed modification of the test setup 110.

Thus, in some cases, the user may have a real-life view of the test setup 110, such as through glasses, a visor, or the like, and the labels 704, instructions 706, graphic elements 708, and the like, may be projected onto, or otherwise overlaid on the real-life view. In other examples, the view provided to the user may be a virtual-reality-type video view of the test setup, with the labels 704, instructions 706, graphic elements 708, and the like, overlaid in the video image by rendering the labels 704, instructions 706, graphic elements 708, and the like, as part of the video image of the test setup.

FIG. 7B illustrates an example view 710 that may be presented to the user when the modifications are complete according to some implementations. In this example, suppose that the user has completed all the instructions for modifying the test setup 110 based on the instructions received from the service computing device 102. The AR device 104 and/or the service computing device(s) 102 may verify that the configuration of the test setup matches that of the selected valid setup, such as based on comparison of the current setup with the selected valid setup, which may be performed, e.g., using the process 204 discussed above with respect to FIG. 2. Accordingly, the AR device may present a completion message 712 on the display device(s) 702 indicating that the modification of the test setup has been successfully completed and that the user may proceed with repeating the validation testing.

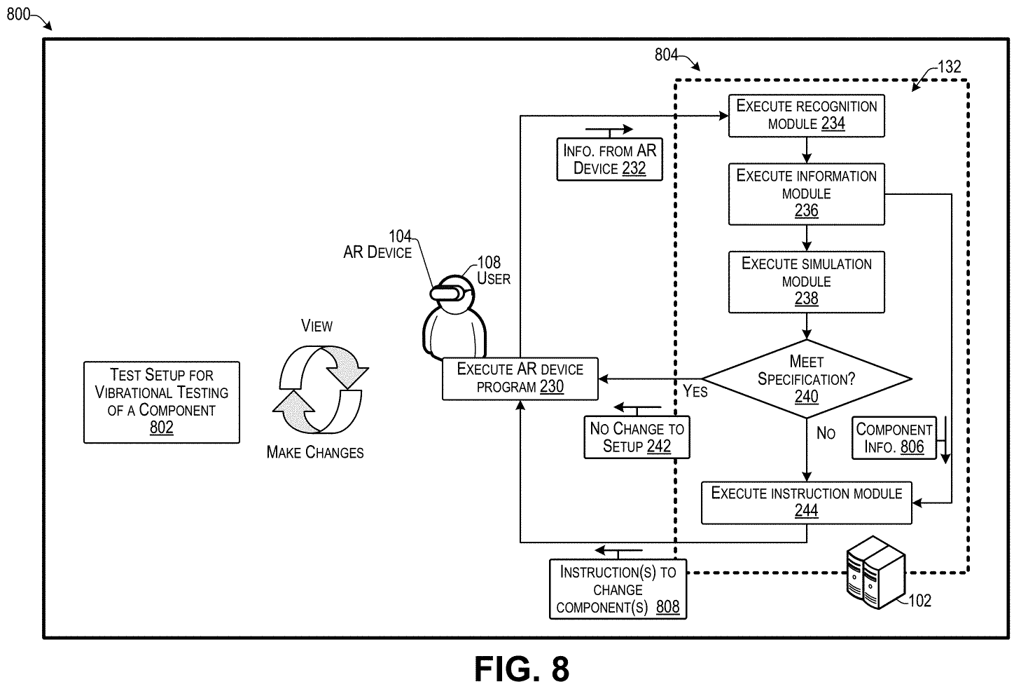

FIG. 8 illustrates an example process 800 for vibrational testing according to some implementations. In addition to application in the field of EMC testing, some implementations herein may be used in other testing fields, testing of other types of components, and the like, such as related to NVH (Noise, Vibration, and Harshness), e.g., such as in the case of vibrational testing and/or vibro-acoustic testing. For example, excellent NVH management is a vehicle development target that contributes to product quality, driving pleasure, and customer satisfaction.

In the example process of FIG. 8, a test setup 802 for vibrational testing of a component may be subject to a process similar to process 202 discussed above with respect to FIG. 2. Examples of test setups for vibrational testing are well known in the art and will not be described in detail. In addition, a process 804 executed by the AR device and the service computing device(s) 102 for the vibrational testing may include a basic workflow similar to that of process 204 of FIG. 2 discussed above, with a difference being the type of information provided by the information module at 236 to the instruction module at 244. In particular, in the case of vibrational testing, component information, rather than layout information may determine the overall vibrational performance of a test setup 802.

In the example process 804 of FIG. 8, therefore, component information 806 may be fed into the instruction module at 244. Accordingly, the instruction module at 244 may evaluate various component changes and may provide instructions 808 to the user to change a component. These component changes, such as in the case of electric machines, might include change of a rotor, rewinding of a stator, use of acoustic insulation or vibration dampers, and so forth. Accordingly, similar to the examples discussed above, the AR device 104 may receive the instructions 808, and may present step-by-step instructions on the display device(s) of the AR device 104 to instruct the user 108 on changing the component(s) of the test setup 802.

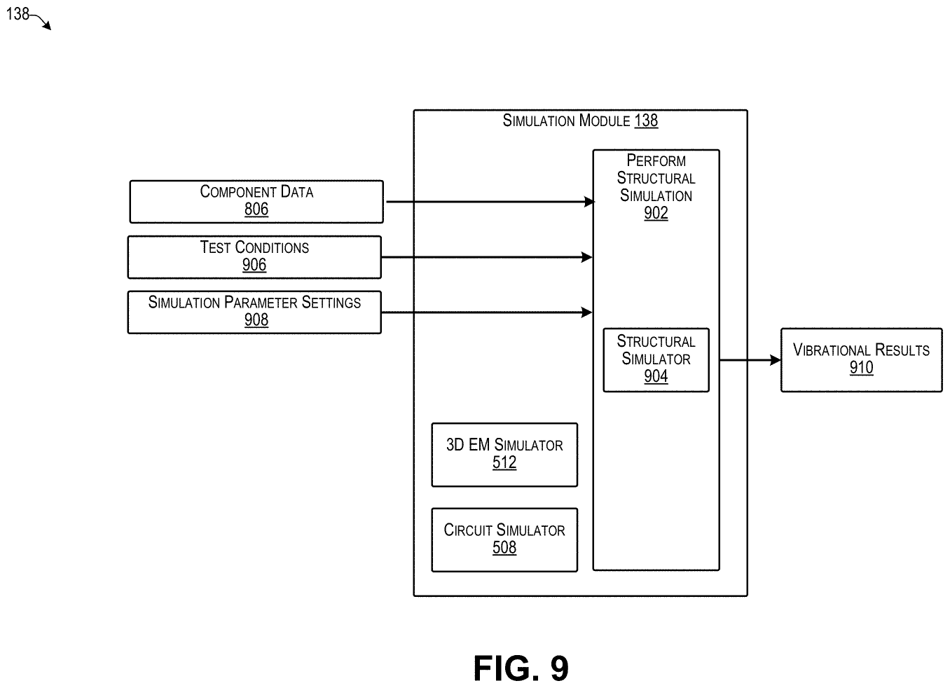

FIG. 9 illustrates an example of the simulation module 138 according to some implementations. In the example of FIG. 9, for performing high fidelity simulation in vibrational testing, the simulation module 138 may be modified to also perform structural simulation. Accordingly, in addition, to including the capability for performing circuit simulation via circuit simulator 508, and 3D EM simulation via the 3D EM simulator, the simulation module 138 illustrated in FIG. 9 includes the capability to perform structural simulation, as indicated at 902. For example, a structural simulator 904 may be included to calculate the vibrational performance of a test setup. The structural simulator 904 may receive, as input, the component information 806 received from the information module, as discussed above with respect to FIG. 8. In addition, the structural simulator 904 may receive test conditions 906 of the vibrational testing, such as based on user input, and simulation parameters settings 908 for the structural simulator 904, which may have been predefined. The structural simulator 904 may output vibrational results 910 that may be used by the instruction module for determining how to modify the components of the vibrational test setup.

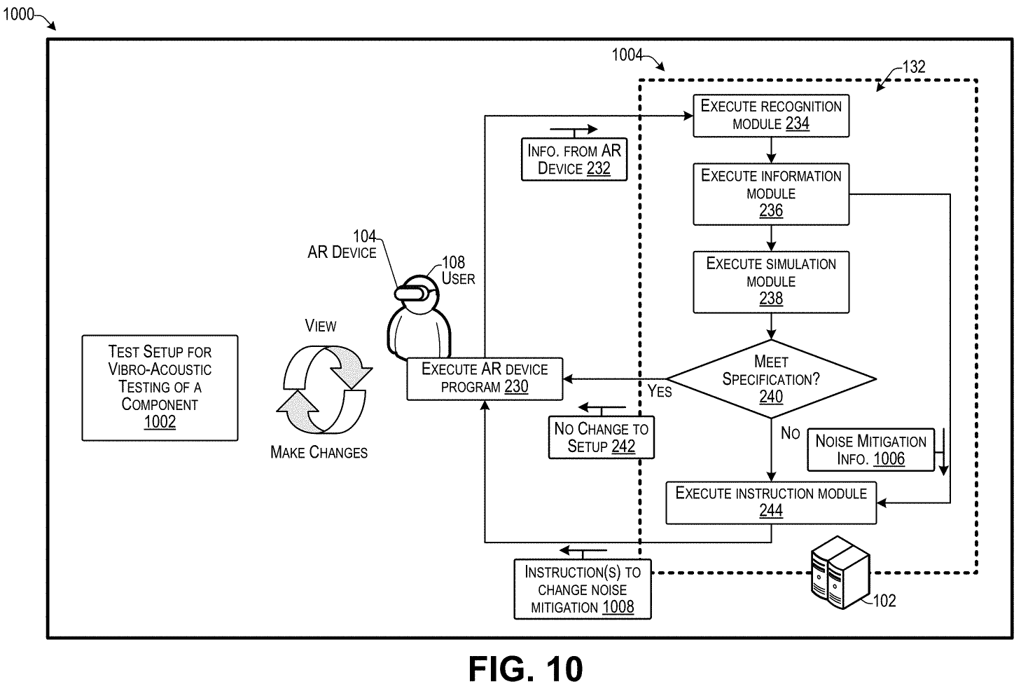

FIG. 10 illustrates an example process 1000 for vibrational-acoustic (vibro-acoustic) testing according to some implementations. In the example process of FIG. 10, a test setup 1002 for vibro-acoustic testing of a component may be subject to a process similar to process 202 discussed above with respect to FIG. 2. Examples of test setups for vibro-acoustic testing are well known in the art and will not be described in detail. In addition, a process 1004 executed by the AR device 104 and the service computing device(s) 102 for the vibro-acoustic testing may include a basic workflow similar to that of process 204 of FIG. 2 discussed above, with a difference being the type of information provided by the information module at 236 to the instruction module at 244. In particular, in the case of vibro-acoustic testing, noise mitigation information, rather than layout information may determine the overall vibro-acoustic performance of the test setup 1002.

In the example process 1004 of FIG. 10, therefore, noise mitigation information 1006 may be provided to the instruction module at 244. Accordingly, the instruction module at 244 may evaluate various noise mitigation techniques corresponding various component changes and may provide instructions 1008 to the user 108 to change a noise mitigation technique for improving the vibro-acoustic test outcome. These noise mitigation techniques, in the case of electric machines, might include skewing, notching, pole shaping, current injection, random pulse width modulation, and so forth. Accordingly, similar to the examples discussed above, the AR device 104 may receive the instructions 1008, and may present step-by-step instructions on the display device(s) of the AR device 104 to instruct the user 108 on changing noise mitigation techniques of the test setup 1002.

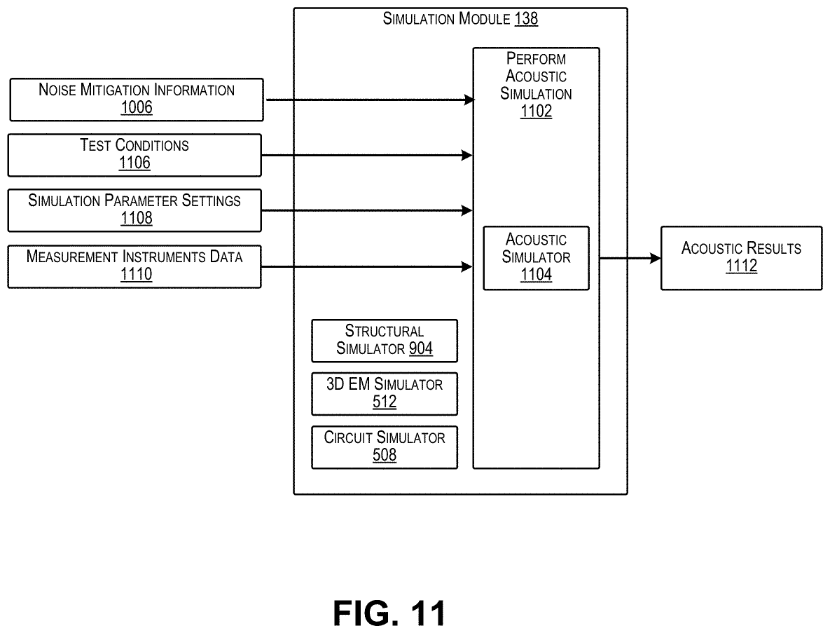

FIG. 11 illustrates an example of the simulation module 138 according to some implementations. In the example of FIG. 11, for performing high fidelity acoustic simulation in vibro-acoustic testing, the simulation module 138 may be modified to also perform acoustic simulation as indicated at 1102. Accordingly, in addition, to including the capability for performing circuit simulation via the circuit simulator 508, 3D EM simulation via the 3D EM simulator 512, and vibrational simulation via the structural simulator 904, the simulation module 138 illustrated in FIG. 11 includes the capability to perform acoustic simulation, as indicated at 1102. For example, an acoustic simulator 1104 may be included to calculate the acoustic performance of a test setup. The acoustic simulator 1104 may receive, as input, the noise mitigation information 1006 received from the information module, as discussed above with respect to FIG. 10. In addition, the acoustic simulator 1104 may receive test conditions 1106 of the vibro-acoustic testing, such as based on user input, and simulation parameters settings 1108 for the acoustic simulator 1104, which may have been predefined.

In addition, the acoustic simulator 1104 may receive measurement instruments data 1110 related to measurement instruments used for measuring the acoustic results of the test setup 1002 of FIG. 10. The acoustic simulator 1104 may output acoustic results 1112 that may be used by the instruction module for determining how to modify the noise mitigation techniques of the vibro-acoustic test setup. In addition, in some cases, the vibrational simulation discussed above with respect to FIGS. 8 and 9 may be performed concurrently with the acoustic simulation discussed with respect to FIGS. 10 and 11. Numerous other variations will be apparent to those of skill in the art having the benefit of the disclosure herein.

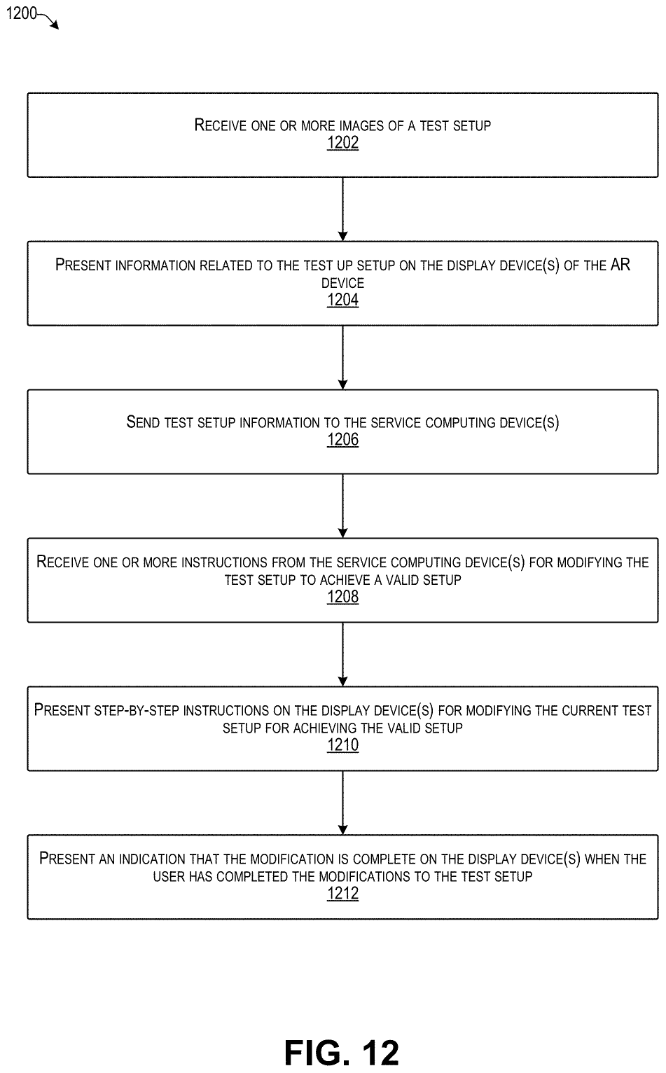

FIG. 12 is a flow diagram illustrating an example process 1200 that may be executed by the AR device 104 according to some implementations. In some examples, the process 1200 may be performed by one or more processors of the AR device 104 by executing the AR device program for performing at least some of the operations described in the process 1200.

At 1202, the AR device may receive one or more images of a test setup. For instance, one or more cameras on the AR device may capture one or more images of the test setup, which may include video of the test setup.

At 1204, the AR device may present information related to the test up setup on the display device(s) of the AR device. For example, the AR device may execute a recognition program similar to that discussed above with respect to FIG. 3, and based on the recognition results, may include labels of the recognized components in the test setup presented on the display device(s) of the AR device.

At 1206, the AR device may send test setup information to the service computing device(s). For example, the AR device may send image information such as video images of the test setup to the service computing device(s). In addition, in some cases, the AR device may send additional information to the service computing device(s) related to the test setup, while in other examples, the additional information may be sent by the test computing device or through various other techniques.

At 1208, the AR device may receive one or more instructions from the service computing device(s) for modifying the test setup. In some examples, the instructions may include step-by-step instructions for instructing the user to modify the test setup. In other examples, the one or more instructions may include an instruction for modifying the test setup to a ballot set up, and the AR device may determine the step-by-step instructions for achieving the valid setup.

At 1210, the AR device may present step-by-step instructions on the display device(s) for modifying the current test setup for achieving the valid setup.

At 1212, the AR device may present an indication that the modification is complete on the display device(s) when the user has completed the modifications to the test setup.

The example processes described herein are only examples of processes provided for discussion purposes. Numerous other variations will be apparent to those of skill in the art in light of the disclosure herein. Further, while the disclosure herein sets forth several examples of suitable systems, architectures and environments for executing the processes, the implementations herein are not limited to the particular examples shown and discussed. Furthermore, this disclosure provides various example implementations, as described and as illustrated in the drawings. However, this disclosure is not limited to the implementations described and illustrated herein, but can extend to other implementations, as would be known or as would become known to those skilled in the art.

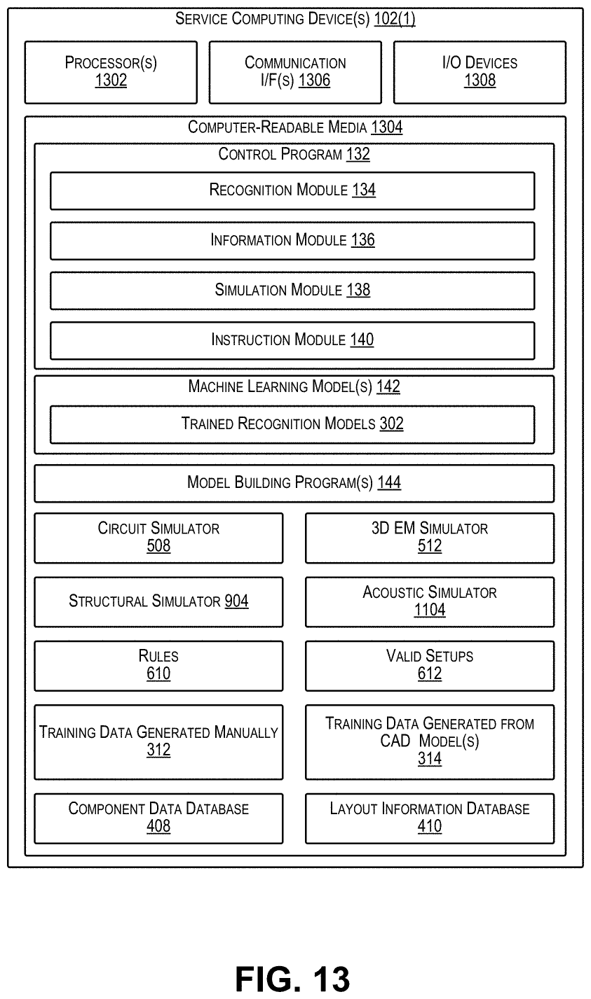

FIG. 13 illustrates select components of the service computing device(s) 102 according to some implementations. The service computing device(s) 102 may include one or more servers or other types of computing devices that may be embodied in any number of ways. For instance, in the case of a server, the programs, other functional components, and data may be implemented on a single server, a cluster of servers, a server farm or data center, a cloud-hosted computing service, and so forth, although other computer architectures may additionally or alternatively be used.

Further, while the figures illustrate the components and data of the service computing device 102 as being present in a single location, these components and data may alternatively be distributed across different computing devices and different locations in any manner. Consequently, the functions may be implemented by one or more service computing devices, with the various functionality described above distributed in various ways across the different computing devices. Multiple service computing devices 102 may be located together or separately, and organized, for example, as virtual servers, server banks, and/or server farms. The described functionality may be provided by the servers of a single entity or enterprise, or may be provided by the servers and/or services of multiple different entities or enterprises.

In the illustrated example, each service computing device 102 may include one or more processors 1302, one or more computer-readable media 1304, one or more communication interfaces 1306, and one or more input/output (I/O) devices 1308. Each processor 1302 may be a single processing unit or a number of processing units, and may include single or multiple computing units or multiple processing cores. The processor(s) 1302 can be implemented as one or more microprocessors, microcomputers, microcontrollers, digital signal processors, central processing units, state machines, logic circuitries, and/or any devices that manipulate signals based on operational instructions. For instance, the processor(s) 1302 may be one or more hardware processors and/or logic circuits of any suitable type specifically programmed or configured to execute the algorithms and processes described herein. The processor(s) 1302 can be configured to fetch and execute computer-readable instructions stored in the computer-readable media 1304, which can program the processor(s) 1302 to perform the functions described herein.

The computer-readable media 1304 may include volatile and nonvolatile memory and/or removable and non-removable media implemented in any type of technology for storage of information, such as computer-readable instructions, data structures, program modules, or other data. Such computer-readable media 1304 may include, but is not limited to, RAM, ROM, EEPROM, flash memory or other memory technology, optical storage, solid state storage, magnetic tape, magnetic disk storage, RAID storage systems, storage arrays, network attached storage, storage area networks, cloud storage, or any other medium that can be used to store the desired information and that can be accessed by a computing device. Depending on the configuration of the service computing device 102, the computer-readable media 1304 may be a tangible non-transitory media to the extent that, when mentioned, non-transitory computer-readable media exclude media such as energy, carrier signals, electromagnetic waves, and signals per se.

The computer-readable media 1304 may be used to store any number of functional components that are executable by the processors 1302. In many implementations, these functional components comprise instructions or programs that are executable by the processors 1302 and that, when executed, specifically configure the one or more processors 1302 to perform the actions attributed above to the service computing device 102. Functional components stored in the computer-readable media 1304 may include the control program 132, including the recognition module 134, the information module 136, the simulation module 138 and the instruction module 140. Each of these functional components 134-140 may be an executable program module of the control program 132, or a portion thereof. Alternatively, in other examples, some or all of these components 134-140 may be separately executable stand-alone computer programs that may be invoked by the management program(s) 122. Additional functional components stored in the computer-readable media 1304 may include the model building program(s) 144, the circuit simulator 508, the 3D EM simulator 512, the structural simulator 904, the acoustic simulator 1104, and an operating system (not shown in FIG. 13) for controlling and managing various functions of the service computing device 102.

In addition, the computer-readable media 1304 may store data and data structures used for performing the functions and services described herein. For example, the computer-readable media 1304 may store the machine learning models 142, including the trained recognition models 302, the rules 610, the valid setups 612, the training data 312 generated manually, the training data generated from CAD models, the component data database 408, and the layout information database 410. Furthermore, while several types of machine learning models and associated programs for training and executing the respective machine learning models are illustrated in this example, additional or alternative types of machine learning models and associated programs may be included in other examples, as will be apparent to those of skill in the art having the benefit of the disclosure herein.

The service computing device 102 may also include or maintain other functional components and data not specifically shown in FIG. 13, which may include programs, drivers, etc., and the data used or generated by the functional components. Further, the service computing device 102 may include many other logical, programmatic, and physical components, of which those described above are merely examples that are related to the discussion herein.

The communication interface(s) 1306 may include one or more interfaces and hardware components for enabling communication with various other devices, such as over the network(s) 106. For example, communication interface(s) 1306 may enable communication through one or more of the Internet, cable networks, cellular networks, wireless networks (e.g., Wi-Fi) and wired networks (e.g., fiber optic and Ethernet), as well as short-range communications, such as BLUETOOTH®, BLUETOOTH® low energy, and the like, as additionally enumerated elsewhere herein.

The service computing device 102 may further be equipped with various input/output (I/O) devices 1308. Such I/O devices 1308 may include a display, various user interface controls (e.g., buttons, joystick, keyboard, mouse, touch screen, etc.), audio speakers, connection ports and so forth.

FIG. 14 illustrates select example components of the AR device 104 according to some implementations. The AR device 104 may include any of a number of different types of computing devices. Some examples of the AR device 104 may include helmets, goggles, visors, or glasses with onboard processor(s) and/or connectable to another computing device. Additional examples of the AR device 104 may include smart phones and mobile communication devices, tablet computing devices, laptops, netbooks and/or other portable computers having an onboard camera. Further, in some examples, the AR device 104 may be connected to a stationary or semi-stationary computing device, such as a desktop computer or other device with computing capabilities, or to a server over the one or more networks. Thus, at least a portion of the functionality of the AR device 104 may be remotely located in some examples. Additionally, in some cases, the AR device 104 may be connected to a computing device or to the one or more networks via a fiber optic connection (not shown in FIG. 14), or the like, to minimize generation of extraneous electromagnetic radiation proximate to the test setup.

In the example of FIG. 14, the AR device 104 includes components such as at least one processor 1402, one or more computer-readable media 1404, one or more communication interfaces 1406, and one or more input/output (I/O) devices 1408. Each processor 1402 may itself comprise one or more processors or processing cores. For example, the processor 1402 can be implemented as one or more microprocessors, microcomputers, microcontrollers, digital signal processors, central processing units, state machines, logic circuitries, and/or any devices that manipulate signals based on operational instructions. In some cases, the processor 1402 may be one or more hardware processors and/or logic circuits of any suitable type specifically programmed or configured to execute the algorithms and processes described herein. The processor 1402 can be configured to fetch and execute computer-readable processor-executable instructions stored in the computer-readable media 1404.

Depending on the configuration of the AR device 104, the computer-readable media 1404 may be an example of tangible non-transitory computer storage media and may include volatile and nonvolatile memory and/or removable and non-removable media implemented in any type of technology for storage of information such as computer-readable processor-executable instructions, data structures, programs, modules, or other data. The computer-readable media 1404 may include, but is not limited to, RAM, ROM, EEPROM, flash memory, solid-state storage, magnetic disk storage, optical storage, and/or other computer-readable media technology. Further, in some cases, the AR device 104 may access external storage, such as RAID storage systems, storage arrays, network attached storage, storage area networks, cloud storage, or any other medium that can be used to store information and that can be accessed by the processor 1402 directly or through another computing device or network. Accordingly, the computer-readable media 1404 may be computer storage media able to store instructions, programs, or components that may be executed by the processor 1402. Further, when mentioned, non-transitory computer-readable media exclude media such as energy, carrier signals, electromagnetic waves, and signals per se.

The computer-readable media 1404 may be used to store and maintain any number of functional components that are executable by the processor 1402. In some implementations, these functional components comprise instructions or programs that are executable by the processor 1402 and that, when executed, implement operational logic for performing the actions and services attributed above to the AR device 104. Functional components of the AR device 104 stored in the computer-readable media 1404 may include the AR device program 1410, as discussed above, which may control the functions of the AR device 104, including camera(s) and other sensors, present information on one or more displays of the AR device 104, and communicate with the service computing device(s) 102. In addition, in some cases, the AR device 104 may include a recognition program 1412 that may perform recognition of a test setup for identifying and labeling components included in a test setup. The recognition program 1412 may be the same as or similar to the recognition module 134 discussed above with respect to FIG. 3. Additional functional components may include an operating system (not shown in FIG. 14) for controlling and managing various functions of the AR device 104 and for enabling basic user interactions with the AR device 104.

In addition, the computer-readable media 1404 may also store data, data structures and the like, as data 1414, which may be used by the functional components, and which, in some cases, may include instructions received from the service computing device(s) 102 and/or images captured by the camera(s). In addition, the computer readable media may store trained recognition models 1416, which may be the same as or similar to the trained recognition models 302 discussed above with respect to FIG. 3, and which may be used by the recognition program 1412. Depending on the type of the AR device 104, the computer-readable media 1404 may also optionally include other functional components and data, which may include applications, programs, drivers, etc., and the data used or generated by the functional components. Further, the AR device 104 may include many other logical, programmatic, and physical components, of which those described are merely examples that are related to the discussion herein.

The communication interface(s) 1406 may include one or more interfaces and hardware components for enabling communication with various other devices, such as over the network(s) 106 or directly. For example, communication interface(s) 1406 may enable communication through one or more of the Internet, cable networks, cellular networks, wireless networks (e.g., Wi-Fi) and wired networks (e.g., fiber optic, Ethernet), as well as short-range communications such as BLUETOOTH®, BLUETOOTH® low energy, and the like, as additionally enumerated elsewhere herein.

FIG. 14 further illustrates that the AR device 104 may include the display device(s) 702, which may employ any suitable display technology. In some examples, the display device(s) 702 may be head-mounted, and may present an independent image to each eye of a user wearing the AR device 104, such as may be provided by one or more cameras 1418. In other examples, the display device(s) 702 may project an image onto the inner surface of a visor, or the like, that enables the user to at least partially see through the displayed information to directly view the user's surroundings. Numerous other variations will be apparent to those of skill in the art having the benefit of the disclosure herein.

The AR device 104 may further include the one or more cameras 1418 and one or more sensors 1420. In some examples, the one or more cameras may provide a separate image to each eye of a user to enable a 3D perception of a view in the cameras' field of view. In other examples, the camera(s) may capture images of the view through the AR device 104, but the captured images might only be sent to the service computing device and not displayed on the display device(s) 702. The sensors 1420 may include any of various types of sensors, such as a GPS receiver, accelerometer, gyroscope, compass, proximity sensor, and the like.

The AR device 104 may further include the one or more I/O devices 1408. The I/O devices 1408 may include speakers, a microphone, and various user controls (e.g., buttons, a joystick, a keyboard, a keypad, etc.), a haptic output device, a control glove, a hand-held controller, and so forth. Additionally, the AR device 104 may include various other components that are not shown, examples of which include removable storage, a power source, such as a battery and power control unit, and so forth.

Various instructions, processes, and techniques described herein may be considered in the general context of computer-executable instructions, such as programs stored on computer-readable media, and executed by the processor(s) herein. Generally, programs include routines, modules, objects, components, data structures, executable code, etc., for performing particular tasks or implementing particular abstract data types. These programs, and the like, may be executed as native code or may be downloaded and executed, such as in a virtual machine or other just-in-time compilation execution environment. Typically, the functionality of the programs may be combined or distributed as desired in various implementations. An implementation of these programs and techniques may be stored on computer storage media or transmitted across some form of communication media.

Although the subject matter has been described in language specific to structural features and/or methodological acts, it is to be understood that the subject matter defined in the appended claims is not necessarily limited to the specific features or acts described. Rather, the specific features and acts are disclosed as example forms of implementing the claims.

What is claimed:

1. A system comprising:
one or more processors; and
one or more non-transitory computer-readable media maintaining executable instructions, which, when executed by the one or more processors, configure the one or more processors to perform operations comprising:
receiving, from an augmented reality device, at least one image of a test setup;
performing recognition on the at least one image to determine one or more components of the test setup and a layout of the test setup;
executing a simulation of the test setup based at least partially on the one or more components of the test setup and the layout of the test setup;
based on the simulation indicating that the test setup does not meet a specification, comparing a plurality of valid setups with the test setup;
selecting one of the valid setups based on the comparing;
preparing one or more instructions for modifying the test setup to resemble the selected valid setup; and
sending the one or more instructions to the augmented reality device to enable the augmented reality device to present the one or more instructions on a display of the augmented reality device overlaid on a view of the test setup.

2. The system as recited in claim 1, wherein the operation of performing the simulation comprises:
determining a circuit based at least partially on the recognition; and
performing a circuit simulation on the circuit to determine a current in the circuit.

3. The system as recited in claim 2, wherein the operation of performing the simulation further comprises:
inputting the current determined from the circuit simulation to an electromagnetic simulator; and
determining an electromagnetic noise level from the electromagnetic simulator.

4. The system as recited in claim 1, the operations further comprising accessing one or more data sources to determine at least one of a circuit diagram or the one or more components based on a result of the recognition.

5. The system as recited in claim 1, wherein the operation of comparing the plurality of valid setups with the test setup comprises:
retrieving information about a plurality of valid setups;
filtering the plurality of valid setups to determine a subset of valid setups based on similarity to the test setup; and
selecting the selected valid setup based on determining a minimum level of modifications to the test setup to cause the test setup to match the valid setup.

6. The system as recited in claim 1, wherein selecting the selected valid setup further comprises:
ranking the valid setups in the subset of valid setups base on an amount of modifications for modifying the test setup to resemble a respective valid setup in the subset of valid setups; and
selecting, as the selected valid setup, one of the valid setups have a score indicting a least amount of modifications.

7. The system as recited in claim 1, wherein the operation of performing the recognition on the at least one image to determine one or more components of the test setup further comprises using one or more trained recognition models for performing the recognition.

8. A method comprising:
receiving, by one or more processors, from an electronic device, at least one image of a test setup;
performing recognition on the at least one image to determine one or more components of the test setup;
executing a simulation of the test setup based at least partially on the one or more components of the test setup;
based on the simulation indicating that the test setup does not meet a specification, comparing a plurality of valid setups with the test setup;
selecting one of the valid setups based on the comparing;
determining one or more instructions for modifying the test setup based on the selected valid setup; and
sending the one or more instructions to the electronic device to enable presentation of the one or more instructions on a display associated with the electronic device.

9. The method as recited in claim 8, wherein executing the simulation of the test setup comprises executing at least one of: a circuit simulator, an electromagnetic simulator, a structural simulator, or an acoustic simulator.

10. The method as recited in claim 8, wherein executing the simulation comprises:
determining a circuit based at least partially on the recognition;
performing a circuit simulation on the circuit to determine a current in the circuit;
inputting the current determined from the circuit simulation to an electromagnetic simulator; and
determining an electromagnetic noise level from the electromagnetic simulator.

11. The method as recited in claim 8, further comprising accessing one or more data sources to determine at least one of a circuit diagram or the one or more components based on a result of the recognition.

12. The method as recited in claim 8, wherein comparing the plurality of valid setups with the test setup comprises:
retrieving information about a plurality of valid setups;
filtering the plurality of valid setups to determine a subset of valid setups based on similarity to the test setup; and
selecting the selected valid setup based on determining a minimum level of modifications to the test setup to cause the test setup to match the valid setup.

13. The method as recited in claim 8, wherein selecting the selected valid setup further comprises:
ranking the valid setups in the subset of valid setups base on an amount of modifications for modifying the test setup to resemble a respective valid setup in the subset of valid setups; and
selecting, as the selected valid setup, one of the valid setups have a score indicting a least amount of modifications.

14. The method as recited in claim 8, wherein performing the recognition on the at least one image to determine one or more components of the test setup further comprises using one or more trained recognition models for performing the recognition.

15. A device comprising:
a display, a camera, and one or more processors, the one or more processors configured by executable instructions to perform operations comprising:
receiving, from the camera, one or more images of a test setup;
sending a least one of the images of the test setup to a computing device;
receiving, from the computing device, based at least partially on an analysis of the at least one image of the test setup, one or more instructions for modifying the test setup based on a valid setup; and
presenting, on the display, the one or more instructions for modifying the test setup, wherein the one or more instructions presented on the display are overlaid on a view of the test setup.

16. The device as recited in claim 15, the operations further comprising:
performing recognition on at least one of the images to determine one or more components of the test setup; and
presenting, on the display, labels associated with the one or more components of the test setup, wherein the labels are overlaid on the view of the test setup.

17. The device as recited in claim 15, wherein the display includes at least one of:
a projected image of the instructions projected for overlaying a real-life view of the test setup; or
a video image view of the test setup with the instructions rendered to overlay the test setup in the video image view of the test setup.

18. The device as recited in claim 15, wherein the device includes one or more head-mounted displays able to be worn on the head of a user of the device.

19. The device as recited in claim 15, wherein the test setup includes at least one of:
an electromagnetic interference testing test setup;
a vibrational testing test setup; or
a vibrational-acoustic testing test setup.

20. The device as recited in claim 15, wherein the operation of presenting, on the display, the one or more instructions comprises presenting the instructions in a step-by-step manner overlaid on the view of the test setup by:
sending one or more additional images of progress in modification of the test setup to the computing device for analysis of the modification; and
receiving additional instructions from the computing device.
